(19) United States
(12) Patent Application Publication
(10) Pub. No.: US 2022/0158117 A1
(43) Pub. Date: May 19, 2022

(54) DISPLAY PANEL AND DISPLAY APPARATUS

(71) Applicant: KunShan Go-Visionox Opto-Electronics Co., Ltd., Kunshan (CN)

(72) Inventors: Miao CHANG, Kunshan (CN); Lu ZHANG, Kunshan (CN); Chuanzhi XU, Kunshan (CN)

(73) Assignee: KunShan Go-Visionox Opto-Electronics Co., Ltd., Kunshan, JS (CN)

(21) Appl. No.: 17/591,017

(22) Filed: Feb. 2, 2022

Related U.S. Application Data
(63) Continuation of application No. PCT/CN2020/086097, filed on Apr. 22, 2020.

(30) Foreign Application Priority Data
Jan. 2, 2020 (CN) 202010002082.9

(51) Int. Cl. H01L 51/52

(52) U.S. Cl. CPC H01L 51/525; H01L 27/3234

(57) ABSTRACT

A display panel includes a first display region and a second display region; a substrate; a pixel definition layer located on the substrate; a plurality of first spacer columns and a plurality of second spacer columns located on a side of the pixel definition layer facing away from the substrate, the plurality of first spacer columns being distributed in the first display region, and the plurality of second spacer columns being distributed in the second display region, where a proportion of a total area of orthographic projections of the first spacer columns in the first display region on the substrate to an area of the first display region is less than a proportion of a total area of orthographic projections of the second spacer columns in the second display region on the substrate to an area of the second display region.

### CROSS-REFERENCE TO RELATED APPLICATIONS

This application is a continuation of International Application No. PCT/CN2020/086097, filed on Apr. 22, 2020, which claims priority to Chinese Patent Application No. 202010002082.9, filed on Jan. 2, 2020, both of which are hereby incorporated by reference in their entireties.

### TECHNICAL FIELD

The present application relates to the field of display, and particularly to a display panel and a display apparatus.

### BACKGROUND

With the rapid development of electronic devices, the requirements of users on screen-to-body proportions become higher and higher. Thus, full-screen displays for electronic devices are interested more and more by the industry.

Conventional electronic devices such as mobile phones and tablets need integrated front-facing cameras, earpieces, and infrared sensing components. However, prior art electronic devices have poor light transmission in areas such as the front camera, which is not conducive to under-screen integration of the front camera.

### SUMMARY

The present application provides a display panel and a display apparatus, which facilitate the under-screen integration of photosensitive components, improve the screen-to-body proportion, and can ensure the overall strength of the display panel.

In an aspect, according to embodiments of the present application, there is provided a display panel including a first display region and a second display region, the light transmittance of the first display region being greater than the light transmittance of the second display region, and the display panel including: a substrate; a pixel definition layer located on the substrate; a plurality of first spacer columns located on a side of the pixel definition layer facing away from the substrate, the plurality of first spacer columns being distributed in the first display region; and a plurality of second spacer columns located on a side of the pixel definition layer facing away from the substrate, the plurality of second spacer columns being distributed in the second display region, where a proportion of a total area of orthographic projections of the plurality of first spacer columns in the first display region on the substrate to an area of the first display region is smaller than a proportion of a total area of orthographic projections of the plurality of second spacer columns in the second display region on the substrate to an area of the second display region, and the proportion of the total area of the orthographic projections of the first spacer columns in the first display region on the substrate to the area of the first display region is from 0.1% to 0.5%.

In another aspect, embodiments of the present application further provide a display apparatus including the display panel as described above.

According to the display panel and the display apparatus in the embodiments of the present application, the light transmittance of the first display region of the display panel is greater than the light transmittance of the second display region, so that in the display panel, the photosensitive components can be integrated on the back side of the first display region, which realizes the under-screen integration of the photosensitive component such as a camera. The display panel includes the substrate, the pixel definition layer, and the first spacer columns and the second spacer columns located on the side of the pixel definition layer facing away from the substrate. The first spacer columns and the second spacer columns can improve the strength and pressure resistance of the display panel, and keep the display panel away from problems of poor displaying effects such as water waves.

Since the proportion of the total area of the orthographic projections of the first spacer columns in the first display region on the substrate to the area of the first display region is smaller than the proportion of the total area of the orthographic projections of the second spacer columns in the second display region on the substrate to the area of the second display region, the influence of the first spacer columns in the first display region on the light transmittance can be reduced compared with the second display region, which effectively increases the light transmittance of the first display region. Furthermore, the proportion of the total area of the orthographic projections of the first spacer columns in the first display region on the substrate to the area of the first display region is from 0.1% to 0.5%, so that the pressure resistance of the first display region of the display panel can be ensured, and at the same time, the influence of the first spacer columns on the light transmission capability of the first display region is reduced, which further improves the light transmission capability of the first display region, so as to enable the photosensitive components integrated under the screen to work better.

### BRIEF DESCRIPTION OF THE DRAWINGS

Other features, objects, and advantages of the present application will become more apparent from the following detailed description of non-limiting embodiments with reference to the accompanying drawings, in which like or similar reference characters refer to the same or similar features, and which are not necessarily drawn to scale.

FIG. 1 is a top view of a display panel according to an embodiment of the present application.

FIG. 2 is a cross-sectional view along the B-B direction in FIG. 1.

FIG. 3 is an enlarged schematic view of a region Q1 of the display panel shown in FIG. 1.

FIG. 4 is an enlarged schematic view of a region Q2 of the display panel shown in FIG. 1.

FIG. 5 is a cross-sectional view along the C-C direction in FIG. 4.

FIG. 6 is a cross-sectional view along the D-D direction in FIG. 4.

### DETAILED DESCRIPTION

Features and exemplary embodiments of various aspects of the present application are described in detail below. In the following detailed description, numerous specific details are set forth in order to provide a thorough understanding of the present application. The following description of the embodiments is merely intended to provide a better understanding of the application by illustrating examples of the present application. In the drawings and the following description, at least some well-known structures and techniques have not been shown in order to avoid unnecessarily obscuring the present application. In addition, the dimensions of some of the structures may be exaggerated for clarity. Furthermore, the features, structures, or characteristics described below may be combined in any suitable manner in one or more embodiments.

In electronic devices such as mobile phones and tablets, photosensitive components (e.g., front cameras, infrared light sensors, and proximity light sensors) are required to be integrated on the side where display panels are provided. In some embodiments, light-transmitting display regions may be provided on the above-described electronic devices, and the photosensitive components may be arranged on the back of the light-transmitting display regions, so that full-screen displaying by the electronic devices can be realized with the normal operation of the photosensitive components being ensured.

Generally, the display panel is provided with spacer columns to improve the overall strength of the display panel, but the arrangement of the spacer columns may affect the light transmittance of the light-transmitting display region of the display panel. Therefore, for the display panel, the arrangement of the spacer columns should be also considered comprehensively in addition to the improvement of the light transmittance of the display panel.

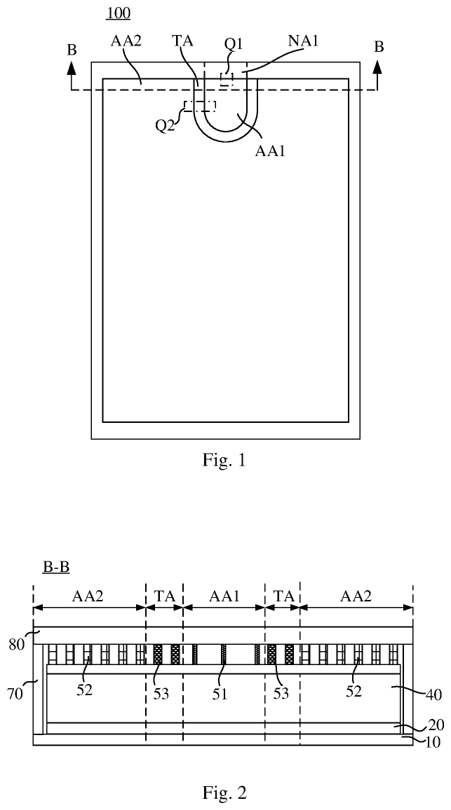

In order to solve the above-mentioned problems, the embodiments of the present application provide a display panel and a display apparatus. The display panel 100 and the display apparatus according to the embodiments of the present application will be described in detail with reference to FIG. 1 to FIG. 6.

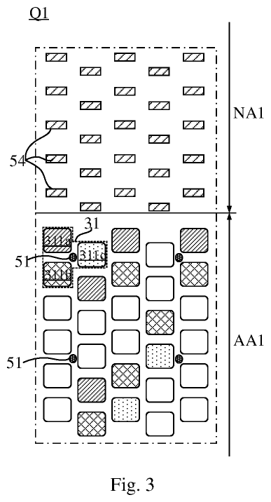

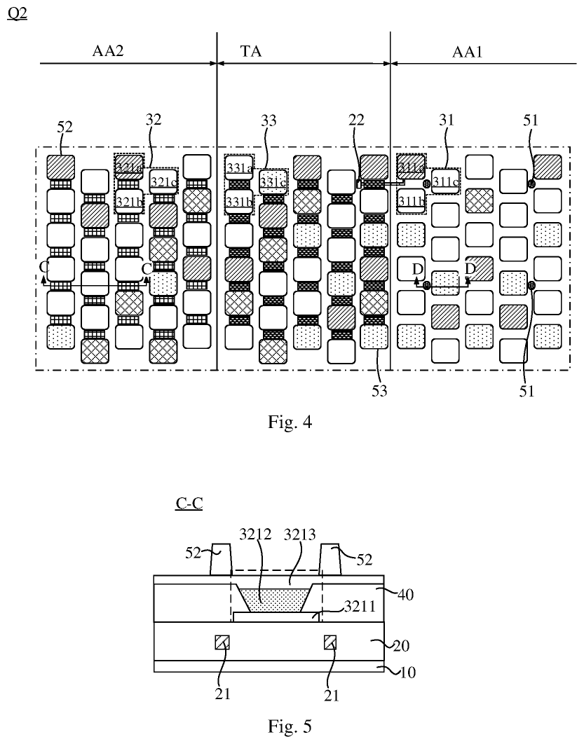

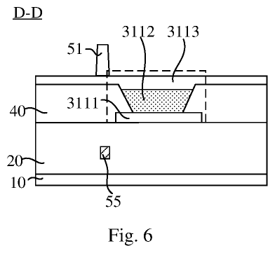

Reference is now made to FIG. 1 to FIG. 6. FIG. 1 illustrates a top view of a display panel according to an embodiment of the present application. FIG. 2 illustrates a cross-sectional view along the B-B direction in FIG. 1. FIG. 3 illustrates an enlarged schematic diagram of a region Q1 of the display panel shown in FIG. 1. FIG. 4 illustrates an enlarged schematic diagram of a region Q2 of the display panel shown in FIG. 1. FIG. 5 illustrates a cross-sectional view along the C-C direction in FIG. 4. FIG. 6 illustrates a cross-sectional view along the D-D direction in FIG. 4.

The embodiments of the present application provide a display panel 100 including a first display region AA1 and a second display region AA2. The light transmittance of the first display region AA1 is greater than the light transmittance of the second display region AA2. The display panel 100 includes a substrate 10, a pixel definition layer 40, and first spacer columns 51 and second spacer columns 52 located on a side of the pixel definition layer 40 facing away from the substrate 10. The pixel definition layer 40 is located on the substrate 10. The first spacer columns 51 are distributed in the first display region AA1, the second spacer columns 52 are distributed in the second display region AA2. A proportion of a total area of orthographic projections of the first spacer columns 51 in the first display region AA1 on the substrate 10 to an area of the first display region AA1 is less than a proportion of a total area of orthographic projections of the second spacer columns 52 in the second display region AA2 on the substrate 10 to an area of the second display region AA2. The proportion of the total area of the orthographic projections of the first spacer columns 51 in the first display region AA1 on the substrate 10 to the area of the first display region AA1 is from 0.1% to 0.5%.

Here, the light transmittance of the first display region AA1 may be 15% or greater. To ensure that the light transmittance of the first display region AA1 is greater than 15%, greater than 40%, or even higher. The light transmittance of at least some of the functional film layers of the display panel 100 in this embodiment is greater than 80%, and the light transmittance of at least some of the functional film layers is even greater than 90%.

By providing the first spacer columns 51 in the first display region AA1 and the second spacer columns 52 in the second display region AA2, on the one hand, the first spacer columns 51 and the second spacer columns 52 can prevent the photomask from scratching the already prepared film in the display panel 100 when vapor deposition is performed on other film structures of the display panel 100 using the photomask. For example, the first spacer columns 51 and the second spacer columns 52 can prevent the photomask from damaging the already prepared light emitting structure when the light emitting structures of the sub-pixels are prepared.

According to this embodiment of the present application, the light transmittance of the first display region AA1 of the display panel 100 is greater than the light transmittance of the second display region AA2, so that in the display panel 100, photosensitive components can be integrated on the back side of the first display region AA1, achieving the under-screen integration of the photosensitive components, such as a camera. The display panel 100 includes a substrate 10, a pixel definition layer 40, and first spacer columns 51 and second spacer columns 52 located on a side of the pixel definition layer 40 facing away from the substrate 10. The first spacer columns 51 and the second spacer columns 52 can improve the strength and pressure resistance of the display panel 100, and keep the display panel 100 from problems of poor display effects such as Moire pattern.

Optionally, the proportion of the total area of the orthographic projections of the first spacer columns 51 in the first display region AA1 on the substrate 10 to the area of the first display region AA1 is from 0.1% to 0.3%. In a specific implementation, the proportion of the total area of the orthographic projections of the first spacer columns 51 of the first display region AA1 on the substrate 10 to the area of the first display region AA1 may be set according to the user's requirements, and may be 0.1%, 0.2% or 0.3%, for example. With the above arrangement, the influence of the first spacer columns 51 on the light transmittance of the first display region AA1 can be reduced, and further, the light transmittance of the first display region AA1 can be maximized while the degree of pressure resistance of the first display region AA1 is guaranteed.

Optionally, the first spacer columns 51 are uniformly distributed in the first display region AA1, and the second spacer columns 52 are uniformly distributed in the second display region AA2. With the above-mentioned arrangement, the first spacer columns 51 can play a function of uniform support in the first display region AA1 to increase the strength of the first display region AA1 at each position. At the same time, light can be uniformly transmitted at each position in the first display region AA1. Similarly, the second spacer columns 52 are uniformly distributed in the second display region AA2, so that the second spacer columns 52 can play a function of uniform support in the second display region AA2, and the strength of each position of the second display region AA2 is increased.

Reference is now made to FIG. 1 and FIG. 3. In order to further improve the pressure resistance of the first display region AA1, in some embodiments, the display panel 100 further includes a first non-display region NA1 adjacent to the first display region AA1, and the display panel 100 further includes compensation spacer columns 54 that are located on the side of the pixel definition layer 40 facing away from the substrate 10 and are distributed in the first non-display region NA1. A proportion of a total area of the orthographic projections of the compensation spacer columns 54 in the first non-display region NA1 on the substrate 10 to the area of the first non-display region NA1 is greater than or equal to the proportion of the total area of the orthographic projections of the second spacer columns 52 in the second display region AA2 on the substrate 10 to the area of the second display region AA2. Optionally, the compensation spacer columns 54 may be uniformly distributed in the first non-display region NA1 in order to make the pressure resistance of the display panel 100 uniform at various positions.

In a specific implementation, the proportion of the total area of the orthographic projections of the first spacer columns 54 in the first non-display region NA1 on the substrate 10 to the area of the first non-display region NA1 is equal to the proportion of the total area of the orthographic projections of the second spacer columns 52 in the second display region AA2 on the substrate 10 to the area of the second display region AA2, so as to compensate for the problem that the pressure resistance of the first display region AA1 and the pressure resistance of the second display region AA2 are uneven due to the proportion of the total area of the orthographic projections of the first spacer columns 51 in the first display region AA1 on the substrate 10 to the area of the first display region AA1 being too small.

Optionally, the proportion of the total area of the orthographic projections of the compensation spacer columns 54 in the first non-display region NA1 on the substrate 10 to the area of the first non-display region NA1 is greater than the proportion of the total area of the orthographic projections of the second spacer columns 52 in the second display region AA2 on the substrate 10 to the area of the second display region AA2, so that the compensation spacer columns 54 can compensate the pressure resistance of the first display region AA1 to a greater extent, so that the pressure resistance of the first display region AA1 approaches the pressure resistance of the second display region AA2.

The display panel 100 may further include a second non-display region surrounding the first display region AA1 and the second display region AA2. The arrangement of the spacer columns in the second non-display region may be set according to the user's requirements, or the spacer columns may not be arranged in the second non-display region.

Optionally, the display panel 100 may further include a cover plate 80. The cover plate 80 is located on the side of the pixel definition layer 40 facing away from the substrate 10. The first spacer columns 51, the second spacer columns 52 and the third spacer columns 53 play a function of support between the pixel definition layer 40 and the cover plate 80. Optionally, in particular embodiments, the display panel 100 is a rigid display panel. With the above arrangement, the stability and the pressure resistance of the display panel 100 can be effectively improved.

Optionally, the display panel 100 further includes an encapsulation structure 70. The encapsulation structure 70 is arranged between the substrate 10 and the cover plate 80. The encapsulation structure 70 is arranged surrounding the first display region AA1 and the second display region AA2 so as to encapsulate the display panel 100 in all directions and improve the display effect and the service life of the display panel 100.

Optionally, the proportion of the total area of the orthographic projections of the second spacer columns 52 on the substrate 10 to the area of the second display region AA2 is from 5% to 15%. With the above arrangement, the pressure resistance of the second display region AA2 can be effectively improved, and particularly, when the display panel 100 is a rigid display panel and the display panel 100 includes the cover plate 80, the cover plate 80 can be more effectively supported by the second spacer columns 52 to improve the strength of the rigid display panel. Optionally, the second spacer columns 52 are uniformly distributed in the second display region AA2, so that the second display region AA2 has a better uniformity in pressure resistance.

Further, reference is made to FIG. 3 and FIG. 4. In order to effectively improve the light transmittance of the first display region AA1 of the display panel 100 and avoid the influence of the first spacer columns 51 on the light transmittance of the first display region AA1, in some embodiments, the shape of the orthographic projection of the first spacer column 51 on the substrate 10 includes a curved profile. Optionally, the orthographic projection of the first spacer column 51 on the substrate 10 is at least one of a circle, an ellipse, a dumbbell shape, and a gourd shape. With the above arrangement, the first spacer column 51 is made smooth at its boundary, and the influence of the first spacer columns 51 having a corner on the transmitted light in the first display region AA1 is prevented.

The display panel 100 further includes a transition display region TA located between the first display region AA1 and the second display region AA2. The display panel 100 further includes a first pixel 31 located in the first display region AA1 and a first pixel circuit 22 located in the transition display region TA. The first pixel circuit 22 is electrically connected to the first pixel 31. The first pixel circuit 22 is configured to drive the first pixel 31 for display. According to the display panel 100 in this embodiment of the present application, the first pixel circuit 22 configured to drive the first pixel 31 for display is located in the transition display region TA, which reduces the wiring structures in the first display region AA1, thereby improving the light transmittance of the first display region AA1.

The display panel 100 further includes third spacer columns 53 located on the side of the pixel definition layer 40 facing away from the substrate 10 and distributed in the transition display region TA. The proportion of the total area of the orthographic projections of the third spacer columns 53 in the transition display region TA on the substrate 10 to the area of the transition display region TA is equal to the proportion of the total area of the orthographic projections of the second spacer columns 52 in the second display region AA2 on the substrate 10 to the area of the second display region AA2. Since the transition display region TA is arranged between the first display region AA1 and the second display region AA2, and the transition display region TA is adjacent to the first display region AA1. With the above arrangement, the third spacer columns 53 in the transition display region TA can compensate the pressure resistance of the first display region AA1 and improve the pressure resistance of the first display region AA1.

Optionally, areas of the orthographic projections of the third spacer columns 53 on the substrate 10 decrease in the direction from the first display region AA1 to the second display region AA2, and/or numbers of third partition columns 53 per unit area of the transition display region TA decrease in the direction from the first display region AA1 to the second display region AA2.

In a specific implementation, on the premise that the proportion of the total area of the orthographic projections of the third spacer columns 53 in the transition display region TA on the substrate 10 to the area of the transition display region TA is consistent, in the direction from the first display region AA1 to the second display region AA2, an area of an orthographic projection of a single third spacer columns 53 on the substrate 10 decreases, and/or numbers of the third spacer columns 53 per unit area of the transition display region TA decrease, so that the total area of the orthographic projections of the third spacer columns 53 on the substrate 10 increases in the direction getting closer to the first display region AA1, so as to more effectively compensate the pressure resistance of the first display region AA1. The transition display region TA is located between the first display region AA1 and the second display region AA2, and the second spacer columns 52 in the second display region AA2 can compensate the positions in the transition display region TA where the pressure resistance is small, thereby effectively improving the pressure resistance of the display panel 100 as a whole.

In order to make the pressure resistance of the transition display region TA uniform, the third spacer columns 53 may be uniformly distributed in the transition display region TA.

Optionally, the arrangement of the second spacer columns 52 formed by the second spacer columns 52 in the second display region AA2 is the same as the arrangement of the third spacer columns 53 formed by the third spacer columns 53 in the transition display region TA. Optionally, the third spacer columns 53 is the same as the second dividing column 52 in size and shape. With the above-mentioned arrangement, the pressure resistance of the second display region AA2 and the transition display region TA is made uniform, and the synchronous production of the second spacer column 52 and the third spacer column 53 is facilitated, and at the same time, the second spacer column 52 and the third spacer column 53 can share a mask, which saves costs.

The specific structures and arrangements on the display panel 100 of the pixel structure, the first spacer column 51, the second spacer column 52 and the third spacer column 53 in the display panel 100 according to this embodiment of the present application will be described with reference to FIG. 3 to FIG. 6.

The display panel 100 includes first pixels 31 located in the first display region AA1. Each first pixel 31 includes a first sub-pixel 311. The display panel 100 further includes second pixels 32 located in the second display region AA2, and the second pixel 32 includes a plurality of second sub-pixels 321. In some embodiments, the first sub-pixel 311 and the second sub-pixel 321 each include multiple sub-pixels of different colors. The first sub-pixel 311 may include a red first sub-pixel 311a, a green first sub-pixel 311b, and a blue first sub-pixel 311c. Similarly, the second pixel 32 of the display panel in the second display region AA2 may include one red second sub-pixel 321a, one green second sub-pixel 321b and one blue second sub-pixel 321c. In FIG. 3 and FIG. 4, sub-pixels of different colors are distinguished by different fill patterns, where sub-pixels of the same color are drawn using the same fill pattern.

The number and the colors of sub-pixels included in each first pixel 31 or each second pixel 32 may be adjusted according to the design requirements of the display panel 100, and thus are not limited to the examples of the embodiments described above. In addition, the arrangement between the sub-pixels in each first pixel 31 or each second pixel 32 is not limited to the examples of the embodiments described above.

When the display panel 100 further includes the transition display region TA, the display panel 100 further includes third pixels 33. The third pixels 33 are located in the transition display region TA. Each third pixel 33 includes third sub-pixels 331. The third sub-pixel 331 may include a red third sub-pixel 331a, a green third sub-pixel 331b and a blue third sub-pixel 331c. The third pixel arrangement formed between the third sub-pixels 331 is the same as the second pixel arrangement formed between the second sub-pixels 321, so that an obvious display boundary between the two display regions is avoided, and the display effect is improved.

Since the third pixel arrangement is the same as the second pixel arrangement, the second spacer column 52 arrangement formed by the second spacer columns 52 in the second display region AA2 is the same as the third spacer column 53 arrangement formed by the third spacer columns 53 in the transition display region TA, the manufacturing process of the display panel 100 can be effectively simplified, and the manufacturing efficiency of the display panel 100 can be improved.

In a specific implementation, the plurality of second sub-pixels 321 are arranged in an array along the column direction of the display panel 100, the second spacer columns 52 are arranged between the second sub-pixels 321 of the array along the column direction, and the arrangement of the third spacer columns 53 is similar to that of the second spacer columns 52, which will not be described in detail.

In order to prevent the first spacer columns 51 in the first display region AA1 from affecting the light transmittance of the first display region AA1, the three first sub-pixels 311 in the first pixel 31 together form a triangle-shaped arrangement, and at this time, the first spacer columns 51 may be arranged between the triangle-shaped arrangement, that is, the first spacer columns 51 are respectively adjacent to the three first sub-pixels 311. Optionally, the size of the first spacer column 51 is smaller than the size of the second spacer column 52 to further improve the light transmittance of the display panel 100.

Reference is now made to FIG. 5 and FIG. 6. The pixel definition layer 40 includes a first pixel opening, and the first sub-pixel 311 includes a first light emitting structure 3112, a first electrode 3111, and a second electrode 3113. The first light emitting structure 3112 is located within the first pixel opening. The first electrode 3111 is located on a side of the first light emitting structure 3112 facing the substrate 10. The second electrode 3113 is located on a side of the first light emitting structure 3112 facing away from the substrate 10. One of the first electrode 3111 and the second electrode 3113 is an anode and the other is a cathode. The structures of the second sub-pixel 321 and the third sub-pixel 331 are similar to the structure of the first sub-pixel 311. For example, the pixel definition layer 40 further includes the second pixel opening and the third pixel opening. The second sub-pixel 321 includes the second light-emitting structure 3212 and the third electrode 3211 and the fourth electrode 3213. The second light-emitting structure 3212 is arranged in the second pixel opening. The third electrode 3211 is located on a side of the second light emitting structure 3212 facing the substrate 10. The fourth electrode 3213 is located on a side of the second light emitting structure 3212 facing away from the substrate 10. One of the third electrode 3211 and the fourth electrode 3213 is an anode, and the other is a cathode.

The third sub-pixel 331 includes a third light emitting structure, a fifth electrode, and a sixth electrode. The third light emitting structure is located within the third pixel opening. The fifth electrode is located on a side of the third light emitting structure facing the substrate 10. The sixth electrode is located on a side of the third light emitting structure facing away from the substrate 10. One of the fifth electrode and the sixth electrode is an anode and the other is a cathode.

In this embodiment, for illustration, the first electrode 3111, the third electrode 3211, and the fifth electrode are taken as anodes, and the second electrode 3113, the fourth electrode 3213, and the sixth electrode are taken as cathodes.

In order to improve the light transmittance of the first display region AA1, the first electrode 3111 is a light-transmitting electrode, and optionally, the first electrode 3111 includes an indium tin oxide (ITO) layer or an indium zinc oxide layer.

Optionally, the first electrode 3111 is a reflective electrode and the area of the orthographic projection of the first electrode 3111 on the substrate 10 is smaller than the area of the orthographic projection of the third electrode 3211 on the substrate 10. The first electrode 112 may include a first light-transmitting conductive layer, a reflective layer located on the first light-transmitting conductive layer, and a second light-transmitting conductive layer located on the reflective layer. The first light-transmitting conductive layer and the second light-transmitting conductive layer may be ITO, indium zinc oxide, etc. and the reflective layer may be a metal layer, for example made of a silver material.

Optionally, the third electrode 3211 and the fifth electrode are reflective electrodes, and the third electrode 3211 and the fifth electrode may be made of the same material as the first electrode 3111.

Optionally, the second electrode 3113 includes a magnesium-silver alloy layer. The fourth electrode 3213 and the sixth electrode may each be configured of the same material as the second electrode 3113. In some embodiments, the second electrode 3113, the fourth electrode 3213, and the sixth electrode may be interconnected as a common electrode.

Further, the first spacer columns 51, the second spacer columns 52 and the third spacer columns 53 are provided in the non-open area of the pixel definition layer 40 to support the display panel 100 while preventing damage to the light emitting structures in the sub-pixels.

When manufacturing the display panel 100, it is necessary to uniform the manufacturing heights of the first spacer columns 51, the second spacer columns 52 and the third spacer columns 53, and make the heights of the first spacer column 51, the second spacer column 52 and the third spacer column 53 level with one another on the side facing away from the substrate 10 to prevent Newton ring from being generated due to the non-uniform heights of the spacers columns.

In order to improve the light transmittance of the first display region AA1, when the first pixel circuit 22 for driving the first pixel 31 to emit light for display is arranged in the transition display region TA, since no driving signal wiring is arranged in the first display region AA1, the film structures of the first display region AA1, the second display region AA2 and the transition display region TA are changed, which may result in the generation of a Newton ring.

In order to address the above problems, in some embodiments, the display panel 100 further includes a device layer 20 and a support structure 55. The device layer 20 is provided between the substrate 10 and the pixel definition layer 40. The device layer 20 includes a conductive structure 21 that is located at the transition display region TA and the second display region AA2. The support structure 55 is located at the first display region AA1. The support structure 55 is in the same layer as the conductive structure 21. The orthographic projection of the support structure 55 on the substrate 10 overlaps with the orthographic projection of the first spacer column 51 on the substrate 10. The support structure 55 makes the side of the first spacer columns 51 facing away from the substrate 10, the side of the second spacer columns 52 facing away from the substrate 10 and the side of the third spacer columns 53 facing away from the substrate 10 level with one another in the thickness direction of the display panel 100. With the above arrangement, the generation of a Newton ring in the first display region AA1 due to the height of the first spacer column 51 in the first display region AA1 being lower than the height of the second spacer column 52 in the second display region AA2 can be effectively avoided. At the same time, the orthographic projection of the support structure 55 on the substrate 10 overlaps the orthographic projection of the first spacer column 51 on the substrate 10, avoiding the influence of the support structure 55 on the light transmittance of the first display region AA1.

Optionally, the constituent material of the support structure 55 is the same as the constituent material of the conductive structure 21. For example, the constituent material of the support structure 55 may be a metal. By making the material of the support structure 55 the same as the constituent material of the conductive structure 21, the light transmission circumstances of the first display region AA1 and the second display region AA2 can be made consistent with each other, thereby avoiding a display difference due to the absence of a metal structure in the first display region AA1.

In a specific implementation, the conductive structure 21 may include a conductive electrode, such as a gate electrode, of a thin film Transistor (TFT) on the display panel 100. The conductive structure 21 may further include a conductive plate in a capacitor and a data line, etc. In the embodiments of the present application, the support structure 55 can be arranged on the same layer as any layer of the conductive electrode, the capacitive conductive plate or the data line of the thin film transistor. Meanwhile, multiples support structure 55 may be included in the thickness direction of the display panel 100.

In summary, according to the display panel 100 of the embodiments of the present application, the light transmittance of the first display region AA1 of the display panel 100 is greater than the light transmittance of the second display region AA2 of the display panel 100, so that in the display panel 100, the photosensitive components can be integrated on the back side of the first display region AA1, which realizes the under-screen integration of the photosensitive component such as a camera. The display panel 100 includes the substrate 10, the pixel definition layer 40, and the first spacer columns 51 and the second spacer columns 52 located on the side of the pixel definition layer 40 facing away from the substrate 10. The first spacer columns 51 and the second spacer columns 52 can improve the strength and pressure resistance of the display panel 100, and keep the display panel 100 away from problems of poor displaying effects such as water waves.

Since the proportion of the total area of the orthographic projections of the first spacer columns 51 in the first display region AA1 on the substrate 10 to the area of the first display region AA1 is smaller than the proportion of the total area of the orthographic projections of the second spacer columns 52 in the second display region AA2 on the substrate 10 to the area of the second display region AA2, the influence of the first spacer columns 51 in the first display region AA1 on the light transmittance can be reduced compared with the second display region AA2, which effectively increases the light transmittance of the first display region AA1. Furthermore, the proportion of the total area of the orthographic projections of the first spacer columns 51 in the first display region AA1 on the substrate 10 to the area of the first display region AA1 is from 0.1% to 0.5%, so that the pressure resistance of the first display region AA1 of the display panel 100 can be ensured, and at the same time, the influence of the first spacer columns 51 on the light transmission capability of the first display region AA1 is reduced, which further improves the light transmission capability of the first display region AA1, so as to enable the photosensitive components integrated under the screen to work better.

In another aspect, the embodiments of the present application further provide a display apparatus including the display panel 100 as described above.

Since the display apparatus according to the embodiments of the present application includes the display panel 100 in any of the above embodiments, the display panel 100 includes the first display region AA1 and the second display region AA2, and the light transmittance of the first display region AA1 is greater than the light transmittance of the second display region AA2. Therefore, the display apparatus according to the embodiments of the present application has the same advantageous effects as the display panel 100 according to the above embodiments, and can not only realize a full-screen display, but also enable the display panel 100 to have a high light transmittance, and facilitate the under-screen integration of components such as photosensitive components.

The display panel 100 includes opposing first and second surfaces, where the first surface is a surface for display. The display apparatus further includes a photosensitive component positioned on the second surface side of the display panel 100. The photosensitive component corresponds to the first display region AA1 in position.

The photosensitive component may be an image capture apparatus for capturing external image information. In some embodiments, the photosensitive component may be a complementary metal oxide semiconductor (CMOS) image capture apparatus. In some other embodiments, the photosensitive component may be a charge-coupled device (CCD) image capture device or other form of image capture device. The photosensitive component may not be limited to an image capture device, for example, in some embodiments, the photosensitive component may be a light sensor such as an infrared sensor, a proximity sensor, an infrared lens, a flood sensing element, an ambient light sensor, and a dot matrix projector. In addition, in the display apparatus, other components may further be integrated on the second surface side of the display panel 100, such as an earpiece, a speaker, etc.

According to the display apparatus in the embodiments of the present application, the light transmittance of the first display region AA1 is greater than the light transmittance of the second display region AA2, so that in the display panel 100, a photosensitive component can be integrated on the back side of the first display region AA1 to realize under-screen integration of a photosensitive component such as an image acquisition device. At the same time, the first display region AA1 are able to display pictures to increase the display area of the display panel 100 to realize a full-screen design of the display apparatus. Meanwhile, by appropriately setting the first spacer columns 51 in the first display region AA1 and the second spacer columns 52 in the second display region AA2, the pressure resistance of the display panel 100 can be ensured.

This application may be embodied in other specific forms without departing from its gist or essential characteristics. The present embodiments are therefore to be considered in all respects as illustrative and not restrictive, the scope of the application being indicated by the appended claims rather than by the foregoing description, and all changes which come within the meaning and range of equivalency of the claims are therefore intended to be embraced therein. Furthermore, the different technical features presented in the different embodiments may be combined in a first combination to achieve advantageous effects. Other variations to the disclosed embodiments can be understood and effected by those skilled in the art in practicing the claimed application, from a study of the drawings, the disclosure, and the appended claims.

What is claimed is:

1. A display panel comprising a first display region and a second display region, a light transmittance of the first display region being greater than a light transmittance of the second display region, and the display panel comprising:
a substrate;
a pixel definition layer located on the substrate;
a plurality of first spacer columns located on a side of the pixel definition layer facing away from the substrate, the plurality of first spacer columns being distributed in the first display region; and
a plurality of second spacer columns located on a side of the pixel definition layer facing away from the substrate, the plurality of second spacer columns being distributed in the second display region,
wherein a proportion of a total area of orthographic projections of the plurality of first spacer columns on the substrate to an area of the first display region is less than a proportion of a total area of orthographic projections of the plurality of second spacer columns on the substrate to an area of the second display region, and the proportion of the total area of the orthographic projections of the first spacer columns in the first display region on the substrate to the area of the first display region is from 0.1% to 0.5%.

2. The display panel according to claim 1, wherein the proportion of the total area of the orthographic projections of the first spacer columns on the substrate to the area of the first display region is from 0.1% to 0.3%.

3. The display panel according to claim 1, wherein the first spacer columns are uniformly distributed in the first display, and the second spacer columns are uniformly distributed in the second display region.

4. The display panel according to claim 1, wherein the display panel further comprises a first non-display region adjacent to the first display region, and the display panel further comprises:
compensation spacer columns located on the side of the pixel definition layer facing away from the substrate and distributed in the first non-display region, and a proportion of a total area of orthographic projections of the compensation spacer columns in the first non-display region on the substrate to the area of the first non-display region being greater than or equal to the proportion of the total area of the orthographic projections of the second spacer columns in the second display region on the substrate to the area of the second display region.

5. The display panel according to claim 1, wherein the proportion of the total area of the orthographic projections of the second spacer columns on the substrate to the area of the second display region is from 5% to 15%.

6. The display panel according to claim 1, wherein a shape of an orthographic projection of a first spacer column on the substrate comprises a curved profile.

7. The display panel according to claim 6, wherein the orthographic projection of the first spacer column on the substrate is at least one of a circle, an ellipse, a dumbbell shape, and a gourd shape.

8. The display panel according to claim 1, wherein the display panel further comprises a transition display region located between the first display region and the second display region, the display panel further comprises a first pixel located in the first display region and a first pixel circuit located in the transition display region, the first pixel circuit is electrically connected to the first pixel, the first pixel circuit is configured to drive the first pixels for display, and the display panel further comprises:
a plurality of third spacer columns located on the side of the pixel definition layer facing away from the substrate and distributed in the transition display region, a proportion of a total area of orthographic projections of the plurality of third spacer columns on the substrate to an area of the transition display region being equal to the proportion of the total area of the orthographic projections of the second spacer columns in the second display region on the substrate to the area of the second display region.

9. The display panel according to claim 8, wherein the plurality of third spacer columns are uniformly distributed in the transition display region.

10. The display panel according to claim 8, wherein areas of the orthographic projections of the third columns on the substrate decreases in a direction from the first display region to the second display region.

11. The display panel according to claim 8, wherein numbers of third spacer columns per unit area of the transition display region decrease in a direction from the first display region to the second display region.

12. The display panel according to claim 8, wherein a second spacer column arrangement formed by the second spacer columns in the second display region is the same as a third spacer column arrangement formed by the third spacer columns in the transition display region.

13. The display panel according to claim 12, wherein the third spacer column and the second spacer column are same in size and shape.

14. The display panel according to claim 8, wherein the display panel further comprises:
a device layer disposed between the substrate and the pixel definition layer, the device layer comprising a conductive structure, and the conductive structure being located at the transition display region and the second display region;
a support structure located at the first display region, the support structure being on a same layer as the conductive structure, an orthographic projection of the support structure on the substrate overlapping an orthographic projection of a first spacer column on the substrate, the support structure making a side of the first spacer columns facing away from the substrate, a side of the second spacer columns facing away from the substrate and a side of the third spacer columns facing away from the substrate level with one another in a thickness direction of the display panel.

15. The display panel according to claim 14, wherein a constituent material of the support structure is the same as a constituent material of the conductive structure.

16. The display panel according to claim 8, wherein the display panel further comprises a cover plate located on the side of the pixel definition layer facing away from the substrate, and the first spacer columns, the second spacer columns and the third spacer columns play a function of supporting between the pixel definition layer and the cover plate.

17. The display panel according to claim 1, wherein the display panel is a rigid display panel.

18. A display apparatus comprising the display panel according to claim 1.
